(19) United States
(12) Patent Application Publication
(10) Pub. No.: US 2024/0421476 A1
(43) Pub. Date: Dec. 19, 2024

(54) ELECTRONIC DEVICE

(71) Applicant: Innolux Corporation, Miaoli County (TW)

(72) Inventors: Chih-Yung Hsieh, Miaoli County (TW); Kazuyuki Hashimoto, Miaoli County (TW)

(73) Assignee: Innolux Corporation, Miaoli County (TW)

(21) Appl. No.: 18/595,431

(22) Filed: Mar. 5, 2024

Related U.S. Application Data
(60) Provisional application No. 63/521,099, filed on Jun. 15, 2023.

(51) Int. Cl. H01Q 3/22

(52) U.S. Cl. CPC H01Q 3/22

(57) ABSTRACT

An electronic device is provided. The electronic device includes a plurality of electronic units. Each of the plurality of electronic units includes a pixel circuit and a tunable component. The tunable component is coupled to the pixel circuit. The pixel circuit includes a storage capacitor, a first scan transistor and a second scan transistor. The first scan transistor is coupled to the storage capacitor. The second scan transistor is coupled to the storage capacitor.

### CROSS-REFERENCE TO RELATED APPLICATION

This application claims the priority benefit of U.S. provisional application Ser. No. 63/521,099, filed on Jun. 15, 2023. The entirety of the above-mentioned patent application is hereby incorporated by reference herein and made a part of this specification.

### BACKGROUND

### Technical Field

The disclosure relates a device; particularly, the disclosure relates to an electronic device.

### Description of Related Art

A general beam-steerable directional antenna consists of a plurality of antenna units, and each of the antenna units may include a tunable component (e.g. varactor) and a pixel circuit. A resonance frequency of the each of the antenna units may be tuned by a control signal of the tunable component, which driven by the pixel circuit. Although a wider voltage range of the control signal can extent tuning range but induces reliability issue, especially on-current degradation of a scan transistor of the pixel circuit by a drain-avalanche hot carrier (DAHC) stress.

### SUMMARY

The electronic device of the disclosure includes a plurality of electronic units. Each of the plurality of electronic units includes a pixel circuit and a tunable component. The tunable component is coupled to the pixel circuit. The pixel circuit includes a storage capacitor, a first scan transistor, and a second scan transistor. The first scan transistor is coupled to the storage capacitor. The second scan transistor is coupled to the storage capacitor.

Based on the above, according to the electronic device of the disclosure, the electronic device may effectively drive the tunable component by controlling at least two scan transistors.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of an electronic device according to an embodiment of the disclosure.

FIG. 2 is a schematic diagram of a pixel circuit and a tunable component according to an embodiment of the disclosure.

FIG. 3 is a timing diagram of relevant signals according to the embodiment of the FIG. 2.

FIG. 4 is a schematic diagram of a pixel circuit and a tunable component according to an embodiment of the disclosure.

FIG. 5 is a timing diagram of relevant signals according to the embodiment of the FIG. 4.

FIG. 6 is a schematic diagram of a pixel circuit and a tunable component according to an embodiment of the disclosure.

FIG. 7 is a timing diagram of relevant signals according to the embodiment of the FIG. 6.

FIG. 8 is a schematic diagram of a pixel circuit and a tunable component according to an embodiment of the disclosure.

FIG. 9 is a schematic diagram of a driving circuit according to an embodiment of the disclosure.

FIG. 10 is a schematic diagram of a driving circuit according to an embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numbers are used in the drawings and the description to refer to the same or like components.

Certain terms are used throughout the specification and appended claims of the disclosure to refer to specific components. Those skilled in the art should understand that electronic device manufacturers may refer to the same components by different names. This article does not intend to distinguish those components with the same function but different names. In the following description and rights request, the words such as “comprise” and “include” are open-ended terms, and should be explained as “including but not limited to . . . ”.

The term “coupling (or connection)” used throughout the whole specification of the present application (including the appended claims) may refer to any direct or indirect connection means. For example, if the text describes that a first device is coupled (or connected) to a second device, it should be interpreted that the first device may be directly connected to the second device, or the first device may be indirectly connected through other devices or certain connection means to be connected to the second device. The terms “first”, “second”, and similar terms mentioned throughout the whole specification of the present application (including the appended claims) are merely used to name discrete elements or to differentiate among different embodiments or ranges. Therefore, the terms should not be regarded as limiting an upper limit or a lower limit of the quantity of the elements and should not be used to limit the arrangement sequence of elements. In addition, wherever possible, elements/components/steps using the same reference numerals in the drawings and the embodiments represent the same or similar parts. Reference may be mutually made to related descriptions of elements/components/steps using the same reference numerals or using the same terms in different embodiments.

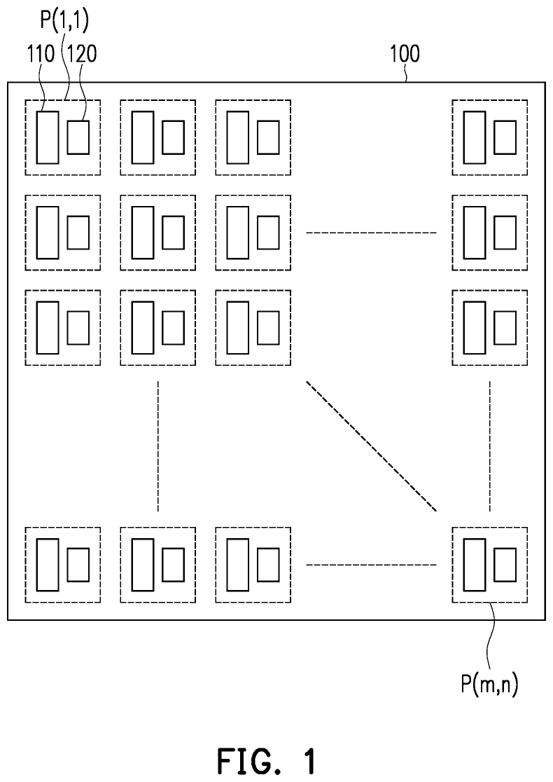

FIG. 1 is a schematic diagram of an electronic device according to an embodiment of the disclosure. Referring to FIG. 1, an electronic device 100 includes a plurality of electronic units P(1,1) to P(m,n), and the electronic units P(1,1) to P(m,n) may be arranged in an array as shown in FIG. 1, where m and n are positive integers. Each of the electronic units P(1,1) to P(m,n) includes a pixel circuit 110 and a tunable component 120, and the pixel circuit 110 is coupled to a tunable component 120. In the embodiment of the disclosure, the tunable component 120 may be a voltage-controlled component (e.g. a variable capacitor, a varactor diode, or a Micro Electro Mechanical System (MEMS)), but the disclosure is not limited thereto. In one embodiment of the disclosure, the tunable component 120 may be a capacitance tunable component. In the embodiment of the disclosure, the electronic device 100 may be an active matrix device. In one embodiment of the disclosure, the electronic device 100 may be an antenna device (e.g. a beam-steerable directional antenna device), and the antenna device may be a liquid crystal antenna or a varactor antenna.

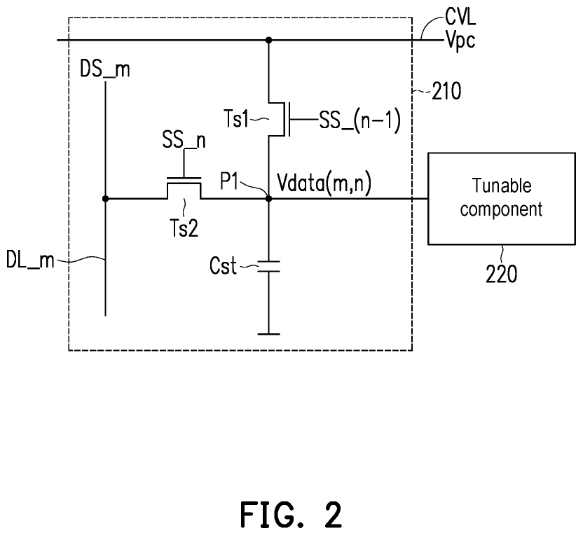

FIG. 2 is a schematic diagram of a pixel circuit and a tunable component according to an embodiment of the disclosure. Referring to FIG. 2, the pixel circuit 110 and the tunable component 120 of each of the electronic units P(1,1) to P(m,n) of FIG. 1 may be implemented as a pixel circuit 210 and a tunable component 220 of FIG. 2. In the embodiment of the disclosure, the pixel circuit 210 includes a first scan transistor Ts1, a second scan transistor Ts2, and a storage capacitor Cst. A first terminal of the first scan transistor Ts1 is coupled to a common voltage line CVL to receive a pre-charge voltage Vpc. The common voltage line CVL (i.e. a dedicated voltage line) may be coupled to all pixels, one row of pixel array, or one column of pixel array. In other words, the common voltage line CVL may be shared with the plurality of electronic units on a same row and/or a same column. A second terminal of the first scan transistor Ts1 is coupled to a circuit node P1. A control terminal of the first scan transistor Ts1 receives a first scan signal SS_(n-1) from a scan line of a previous row of the pixel array. A first terminal of the second scan transistor Ts2 is coupled to a data line DL_m corresponding to a current column of the pixel array to receive a data signal DS_m. A second terminal of the second scan transistor Ts2 is coupled to the circuit node P1. A control terminal of the second scan transistor Ts2 receives a second scan signal SS_n from a scan line of a current row of the pixel array. A first terminal of the capacitor Cst is coupled to the circuit node P1. A second terminal of the capacitor Cst is coupled to a reference voltage, such as a ground voltage. The tunable component 220 is coupled to the circuit node P1. In the embodiment of the disclosure, the first scan transistor Ts1 and the second scan transistor Ts2 may be n-type transistors, but the disclosure is not limited thereto.

In the embodiment of the disclosure, the first scan transistor Ts1 and the second scan transistor Ts2 are turned-on at different times according to the first scan signal SS_(n-1) and the second scan signal SS_n. The first scan transistor Ts1 transfers the pre-charge voltage Vpc to the storage capacitor Cst through the circuit node P1 when the first scan transistor Ts1 is turned-on. The second scan transistor Ts2 receives a data voltage of the data signal DS_m, and transfers the data voltage to the storage capacitor Cst through the circuit node P1 when the second scan transistor Ts2 is turned-on. In the embodiment of the disclosure, the storage capacitor Cst may be pre-charged by the pre-charge voltage Vpc, and then the storage capacitor Cst may be further charged by the data voltage of the data signal DS_m. Therefore, the drain-avalanche hot carrier (DAHC) stress of the first scan transistor Ts1 and the second scan transistor Ts2 can be effectively alleviated by sharing the amount of charge to be transferred to the storage capacitor Cst and the drain-source voltage.

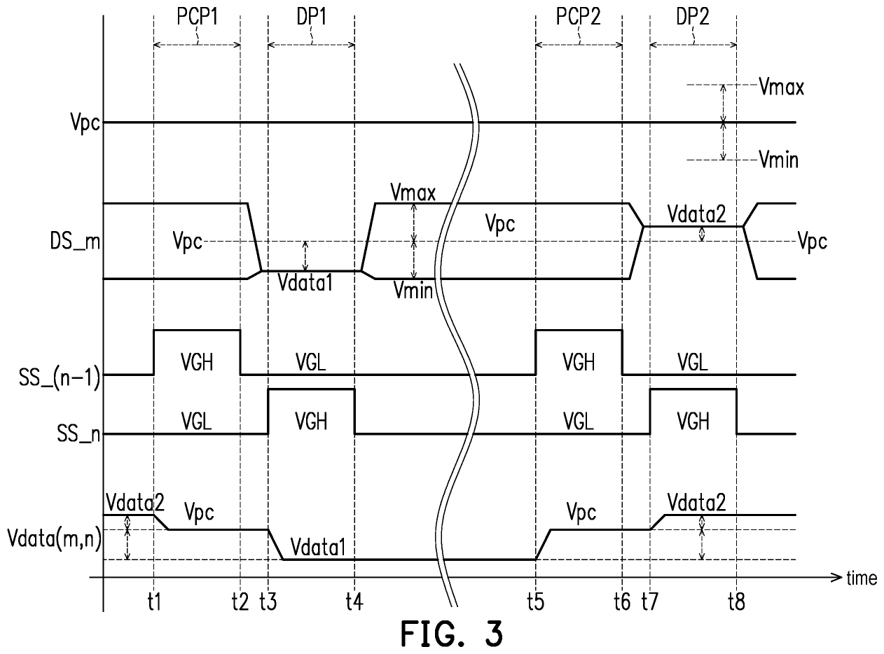

FIG. 3 is a timing diagram of relevant signals according to the embodiment of the FIG. 2. Referring to FIG. 2 and FIG. 3, during a pre-charge period PCP1 from time t1 to time t2, the first scan signal SS_(n-1) may provide a high voltage level VGH, and the second scan signal SS_n may provide a low voltage level VGL. Thus, the first scan transistor Ts1 may be turned-on, and the second scan transistor Ts2 may be turned-off. The first scan transistor Ts1 may transfer the pre-charge voltage Vpc to the circuit node P1, so as to pre-charge the storage capacitor Cst. A voltage Vdata(m,n) of the circuit node P1 may be changed to the pre-charge voltage Vpc. During a driving period DP1 from time t3 to time t4, the first scan signal SS_(n-1) may provide the low voltage level VGL, and the second scan signal SS_n may provide the high voltage level VGH. The data signal DS_m may provide a data voltage Vdata1. Thus, the first scan transistor Ts1 may be turned-off, and the second scan transistor Ts2 may be turned-on. The second scan transistor Ts2 may transfer the data voltage Vdata1 to the circuit node P1, so as to charge the storage capacitor Cst. The voltage Vdata(m,n) of the circuit node P1 may be further changed from the pre-charge voltage Vpc to the data voltage Vdata1. Thus, the storage capacitor Cst may hold the data voltage Vdata1 as a control signal (i.e. a control voltage) of the tunable component 220 after time t4. The tunable component 220 may be controlled by the control signal corresponding to the data voltage Vdata1.

Similarly, during a next pre-charge period PCP2 from time t5 to time t6, the first scan signal SS_(n-1) may provide the high voltage level VGH, and the second scan signal SS_n may provide the low voltage level VGL. Thus, the first scan transistor Ts1 may be turned-on, and the second scan transistor Ts2 may be turned-off. The first scan transistor Ts1 may transfer the pre-charge voltage Vpc to the circuit node P1, so as to pre-charge the storage capacitor Cst. The voltage Vdata(m,n) of the circuit node PI may be changed from the previous data voltage Vdata1 to the pre-charge voltage Vpc. During a next driving period DP2 from time t7 to time t8, the first scan signal SS_(n-1) may provide the low voltage level VGL, and the second scan signal SS_n may provide the high voltage level VGH. The data signal DS_m may provide another data voltage Vdata2. Thus, the first scan transistor Ts1 may be turned-off, and the second scan transistor Ts2 may be turned-on. The second scan transistor Ts2 may transfer the data voltage Vdata2 to the circuit node P1, so as to charge the storage capacitor Cst. The voltage Vdata(m,n) of the circuit node P1 may be further changed from the pre-charge voltage Vpc to the data voltage Vdata2. Thus, the storage capacitor Cst may hold the data voltage Vdata2 as the control signal of the tunable component 220 after time t8. The tunable component 220 may be controlled by the control signal corresponding to the data voltage Vdata2.

In the embodiment of the disclosure, the pre-charge voltage Vpc may be defined to a proper voltage for mitigating the DAHC stress of the first scan transistor Ts1 and the second scan transistor Ts2 during a charging process of the storage capacitor Cst (i.e. during the pre-charge period and the driving period). In the embodiment of the disclosure, the pre-charge voltage Vpc may be a fixed voltage. The pre-charge voltage Vpc may be within a first preset range corresponding to a center of a voltage range of the data voltage of the data signal DS_m. Moreover, the pre-charge voltage Vpc may be equal to or less than a maximum voltage Vmax of the data voltage of the data signal DS_m, and the pre-charge voltage Vpc may be equal to or larger than a minimum voltage Vmin of the data voltage of the data signal DS_m.

In the embodiment of the disclosure, the storage capacitor Cst may be charged in two stages (i.e. the pre-charge period and the driving period), so the first scan transistor Ts1 and the second scan transistor Ts2 may share amount of charge for charging the storage capacitor Cst. Therefore, the DAHC stress of the first scan transistor Ts1 and the second scan transistor Ts2 may be effectively mitigated during the charging process of the storage capacitor Cst.

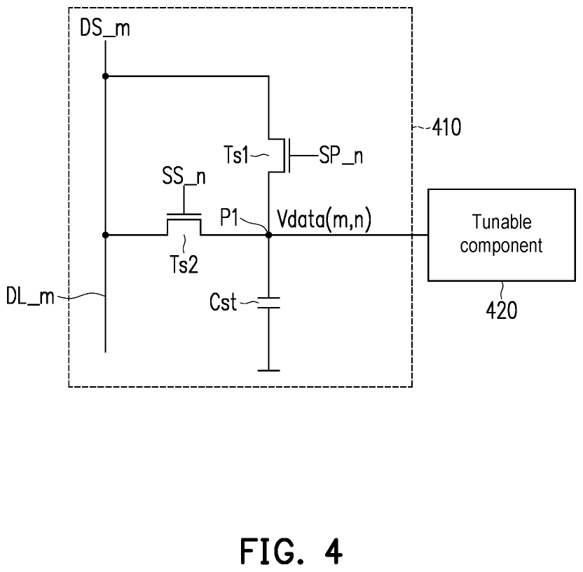

FIG. 4 is a schematic diagram of a pixel circuit and a tunable component according to an embodiment of the disclosure. Referring to FIG. 4, the pixel circuit 110 and the tunable component 120 of each of the electronic units P(1,1) to P(m,n) of FIG. 1 may be implemented as a pixel circuit 410 and a tunable component 420 of FIG. 4. In the embodiment of the disclosure, the pixel circuit 410 includes a first scan transistor Ts1, a second scan transistor Ts2, and a storage capacitor Cst. A first terminal of the first scan transistor Ts1 is coupled to a data line DL_m corresponding to a current column of the pixel array to receive a pre-charge voltage provided by a data signal DS_m. A second terminal of the first scan transistor Ts1 is coupled to a circuit node P1. A control terminal of the first scan transistor Ts1 receives a pre-scan signal SP_n from a pre-scan line of a current row of the pixel array. A first terminal of the second scan transistor Ts2 is coupled to the data line DL_m to receive a data voltage provided by the data signal DS_m. A second terminal of the second scan transistor Ts2 is coupled to the circuit node P1. A control terminal of the second scan transistor Ts2 receives a scan signal SS_n from a scan line of the current row of the pixel array. A first terminal of the capacitor Cst is coupled to the circuit node P1. A second terminal of the capacitor Cst is coupled to a reference voltage, such as a ground voltage. The tunable component 420 is coupled to the circuit node P1. In the embodiment of the disclosure, the first scan transistor Ts1 and the second scan transistor Ts2 may be n-type transistors, but the disclosure is not limited thereto.

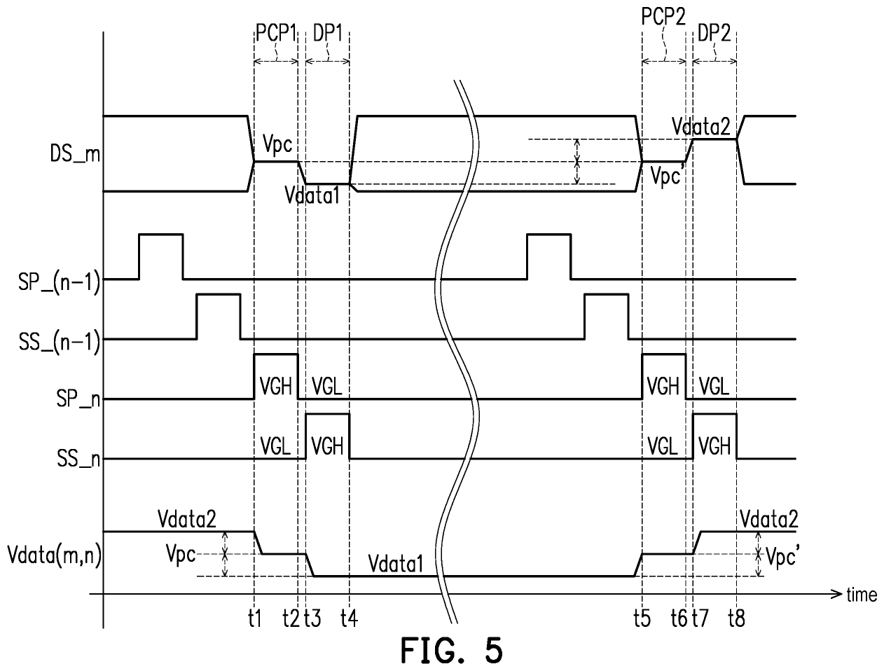

In the embodiment of the disclosure, the data line DL_m may provide the pre-charge voltage and the data voltage of the data signal DS_m in a time-sharing manner. The first scan transistor Ts1 and the second scan transistor Ts2 are turned-on at different times according to the pre-scan signal SP_n and the scan signal SS_n. The first scan transistor Ts1 receives the pre-charge voltage, and transfers the pre-charge voltage to the storage capacitor Cst through the circuit node P1 when the first scan transistor Ts1 is turned-on. The second scan transistor Ts2 receives the data voltage, and transfers the data voltage to the storage capacitor Cst through the circuit node P1 when the second scan transistor Ts2 is turned-on. In the embodiment of the disclosure, the storage capacitor Cst may be pre-charged by the pre-charge voltage, and then the storage capacitor Cst may be further charged by the data voltage. Therefore, the DAHC stress of the first scan transistor Ts1 and the second scan transistor Ts2 can be effectively alleviated by sharing the amount of charge to be transferred to the storage capacitor Cst and the drain-source voltage. FIG. 5 is a timing diagram of relevant signals according to the embodiment of the FIG. 4. Referring to FIG. 4 and FIG. 5, during a pre-charge period PCP1 from time t1 to time t2, the pre-scan signal SP_n may provide a high voltage level VGH, and the scan signal SS_n may provide a low voltage level VGL. Thus, the first scan transistor Ts1 may be turned-on, and the second scan transistor Ts2 may be turned-off. The data signal DS_m may provide the pre-charge voltage Vpc, and the first scan transistor Ts1 may transfer the pre-charge voltage Vpc to the circuit node P1, so as to pre-charge the storage capacitor Cst. A voltage Vdata(m,n) of the circuit node P1 may be changed to the pre-charge voltage Vpc. During a driving period DP1 from time t3 to time t4, the pre-scan signal SP_n may provide the low voltage level VGL, and the scan signal SS_n may provide the high voltage level VGH. Thus, the first scan transistor Ts1 may be turned-off, and the second scan transistor Ts2 may be turned-on. The data signal DS_m may provide the data voltage Vdata1, and the second scan transistor Ts2 may transfer the data voltage Vdata1 to the circuit node P1, so as to charge the storage capacitor Cst. The voltage Vdata(m,n) of the circuit node P1 may be further changed from the pre-charge voltage Vpc to the data voltage Vdata1. Thus, the storage capacitor Cst may hold the data voltage Vdata1 as a control signal (i.e. a control voltage) of the tunable component 420 after time t4. The tunable component 420 may be controlled by the control signal corresponding to the data voltage Vdata1.

Similarly, during a next pre-charge period PCP2 from time t5 to time t6, the pre-scan signal SP_n may provide the high voltage level VGH, and the scan signal SS_n may provide the low voltage level VGL. Thus, the first scan transistor Ts1 may be turned-on, and the second scan transistor Ts2 may be turned-off. The data signal DS_m may provide a pre-charge voltage Vpc′, and the first scan transistor Ts1 may transfer the pre-charge voltage Vpc′ to the circuit node P1, so as to pre-charge the storage capacitor Cst. The voltage Vdata(m,n) of the circuit node P1 may be changed from the previous data voltage Vdata1 to the pre-charge voltage Vpc′. During a next driving period DP2 from time t7 to time t8, the pre-scan signal SP_n may provide the low voltage level VGL, and the scan signal SS_n may provide the high voltage level VGH. Thus, the first scan transistor Ts1 may be turned-off, and the second scan transistor Ts2 may be turned-on. The data signal DS_m may provide another data voltage Vdata2, and the second scan transistor Ts2 may transfer the data voltage Vdata2 to the circuit node P1, so as to charge the storage capacitor Cst. The voltage Vdata(m,n) of the circuit node PI may be further changed from the pre-charge voltage Vpc′ to the data voltage Vdata2. Thus, the storage capacitor Cst may hold the data voltage Vdata2 as the control signal of the tunable component 420 after time t8. The tunable component 420 may be controlled by the control signal corresponding to the data voltage Vdata2.

In the embodiment of the disclosure, the pre-charge voltage Vpc and the pre-charge voltage Vpc′ may be respectively defined to a proper voltage for mitigating the DAHC stress of the first scan transistor Ts1 and the second scan transistor Ts2 during a charging process of the storage capacitor Cst (i.e. during the pre-charge period and the driving period). In the embodiment of the disclosure, the pre-charge voltage Vpc and the pre-charge voltage Vpc′ may be non-fixed voltages. During the pre-charge period PCP2, the pre-charge voltage Vpc′ may be within a second preset range corresponding to a center of a voltage range of a first voltage, and the first voltage may be the current data voltage Vdata2 plus the previous data voltage Vdata1 divided by 2. Moreover, the definition of the pre-charge voltage Vpc may be deduced similarly.

In the embodiment of the disclosure, the storage capacitor Cst may be charged in two stages (i.e. the pre-charge period and the driving period), so the first scan transistor Ts1 and the second scan transistor Ts2 may share amount of charge for charging the storage capacitor Cst. Therefore, the DAHC stress of the first scan transistor Ts1 and the second scan transistor Ts2 may be effectively mitigated during the charging process of the storage capacitor Cst. In addition, in FIG. 5, a pre-scan signal SP_n and a scan signal SS_n show a pre-scan signal and a scan signal for a pixel circuit on a previous row as reference.

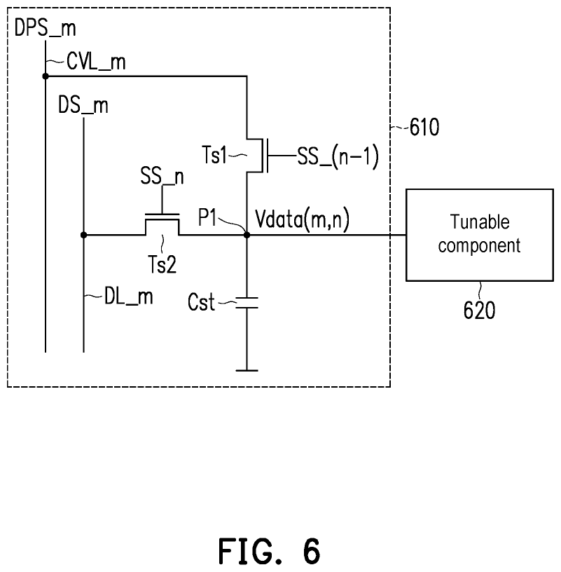

FIG. 6 is a schematic diagram of a pixel circuit and a tunable component according to an embodiment of the disclosure. Referring to FIG. 6, the pixel circuit 110 and the tunable component 120 of each of the electronic units P(1,1) to P(m,n) of FIG. 1 may be implemented as a pixel circuit 610 and a tunable component 620 of FIG. 6. In the embodiment of the disclosure, the pixel circuit 610 includes a first scan transistor Ts1, a second scan transistor Ts2, and a storage capacitor Cst. A first terminal of the first scan transistor Ts1 is coupled to a pre-charge data line CVL_m corresponding to a current column of the pixel array to receive a pre-charge data signal DPS_m. A second terminal of the first scan transistor Ts1 is coupled to a circuit node P1. A control terminal of the first scan transistor Ts1 receives a first scan signal SS_(n-1) from a scan line of a previous row of the pixel array. A first terminal of the second scan transistor Ts2 is coupled to a data line DL_m corresponding to the current column of the pixel array to receive a data signal DS_m. A second terminal of the second scan transistor Ts2 is coupled to the circuit node P1. A control terminal of the second scan transistor Ts2 receives a second scan signal SS_n from a scan line of a current row of the pixel array. A first terminal of the capacitor Cst is coupled to the circuit node P1. A second terminal of the capacitor Cst is coupled to a reference voltage, such as a ground voltage. The tunable component 420 is coupled to the circuit node P1. In the embodiment of the disclosure, the first scan transistor Ts1 and the second scan transistor Ts2 may be n-type transistors, but the disclosure is not limited thereto.

In the embodiment of the disclosure, the first scan transistor Ts1 and the second scan transistor Ts2 are turned-on at different times according to the first scan signal SS_(n-1) and the second scan signal SS_n. The first scan transistor Ts1 is configured to transfer a pre-charge voltage Vpc provided by the pre-charge data signal DPS_m to the storage capacitor Cst through the circuit node P1 when the first scan transistor Ts1 is turned-on. The second scan transistor Ts2 receives a data voltage provided by the data signal DS_m, and configured to transfer the data voltage to the storage capacitor Cst through the circuit node P1 when the second scan transistor Ts2 is turned-on. In the embodiment of the disclosure, the storage capacitor Cst may be pre-charged by the pre-charge voltage of the pre-charge data signal DPS_m, and then the storage capacitor Cst may be charged by the data voltage of the data signal DS_m. Therefore, the drain avalanche hot carrier (DAHC) stress of the first scan transistor Ts1 and the second scan transistor Ts2 can be effectively alleviated by sharing the amount of charge to be transferred to the storage capacitor Cst and the drain-source voltage.

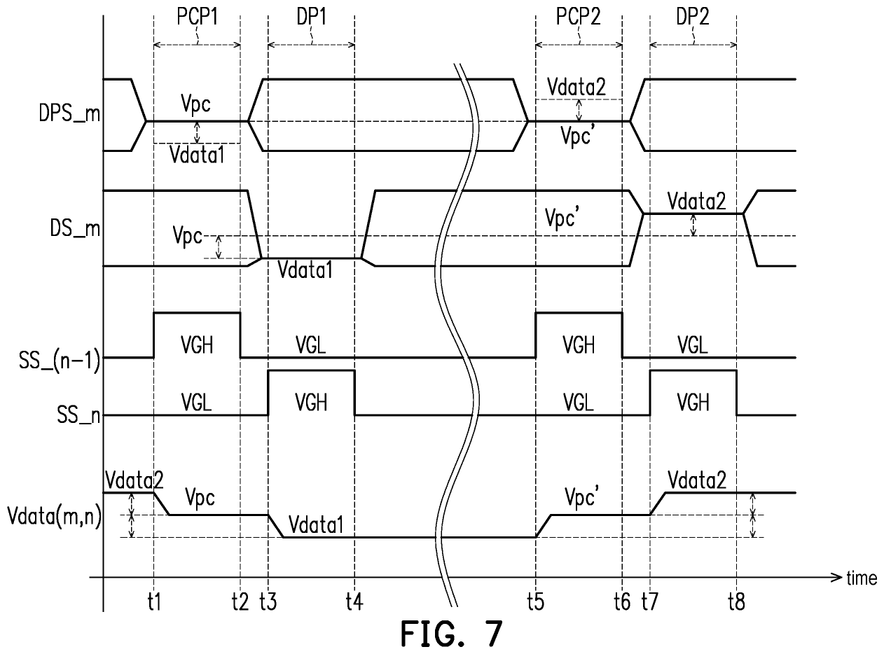

FIG. 7 is a timing diagram of relevant signals according to the embodiment of the FIG. 6. Referring to FIG. 6 and FIG. 7, during a pre-charge period PCP1 from time t1 to time t2, the first scan signal SS_(n-1) may provide a high voltage level VGH, and the second scan signal SS_n may provide a low voltage level VGL. Thus, the first scan transistor Ts1 may be turned-on, and the second scan transistor Ts2 may be turned-off. The pre-charge data signal DPS_m may provide a pre-charge voltage Vpc, and the first scan transistor Ts1 may transfer the pre-charge voltage Vpc to the circuit node P1, so as to pre-charge the storage capacitor Cst. A voltage Vdata(m,n) of the circuit node P1 may be changed to the pre-charge voltage Vpc. During a driving period DP1 from time t3 to time t4, the first scan signal SS_(n-1) may provide the low voltage level VGL, and the second scan signal SS_n may provide the high voltage level VGH. Thus, the first scan transistor Ts1 may be turned-off, and the second scan transistor Ts2 may be turned-on. The data signal DS_m may provide the data voltage Vdata1, and the second scan transistor Ts2 may transfer the data voltage Vdata1 to the circuit node P1, so as to charge the storage capacitor Cst. The voltage Vdata(m,n) of the circuit node P1 may be further changed from the pre-charge voltage Vpc to the data voltage Vdata1. Thus, the storage capacitor Cst may hold the data voltage Vdata1 as a control signal (i.e. a control voltage) of the tunable component 620 after time t4. The tunable component 620 may be controlled by the control signal corresponding to the data voltage Vdata1.

Similarly, during a next pre-charge period PCP2 from time t5 to time t6, the first scan signal SS_(n-1) may provide the high voltage level VGH, and the second scan signal SS_n may provide the low voltage level VGL. Thus, the first scan transistor Ts1 may be turned-on, and the second scan transistor Ts2 may be turned-off. The pre-charge data signal DPS_m may provide a pre-charge voltage Vpc′, and the first scan transistor Ts1 may transfer the pre-charge voltage Vpc′ to the circuit node P1, so as to pre-charge the storage capacitor Cst. The voltage Vdata(m,n) of the circuit node P1 may be changed from the previous data voltage Vdata1 to the pre-charge voltage Vpc′. During a next driving period DP2 from time t7 to time t8, the first scan signal SS_(n-1) may provide the low voltage level VGL, and the second scan signal SS_n may provide the high voltage level VGH. Thus, the first scan transistor Ts1 may be turned-off, and the second scan transistor Ts2 may be turned-on. The data signal DS_m may provide another data voltage Vdata2, and the second scan transistor Ts2 may transfer the data voltage Vdata2 to the circuit node P1, so as to charge the storage capacitor Cst. The voltage Vdata(m,n) of the circuit node P1 may be further changed from the pre-charge voltage Vpc′ to the data voltage Vdata2. Thus, the storage capacitor Cst may hold the data voltage Vdata2 as the control signal of the tunable component 620 after time t8. The tunable component 620 may be controlled by the control signal corresponding to the data voltage Vdata2.

In the embodiment of the disclosure, the pre-charge voltage Vpc and the pre-charge voltage Vpc′ may be respectively defined to a proper voltage for mitigating the DAHC stress of the first scan transistor Ts1 and the second scan transistor Ts2 during a charging process of the storage capacitor Cst (i.e. during the pre-charge period and the driving period). In the embodiment of the disclosure, the pre-charge voltage Vpc and the pre-charge voltage Vpc′ may be non-fixed voltages. During the pre-charge period PCP2, the pre-charge voltage Vpc′ may be within a second preset range corresponding to a center of a voltage range of a first voltage, and the first voltage may be the current data voltage Vdata2 plus the previous data voltage Vdata1 divided by 2. Moreover, the definition of the pre-charge voltage Vpc may be deduced similarly.

In the embodiment of the disclosure, the storage capacitor Cst may be charged in two stages (i.e. the pre-charge period and the driving period), so the first scan transistor Ts1 and the second scan transistor Ts2 may share amount of charge for charging the storage capacitor Cst. Therefore, the DAHC stress of the first scan transistor Ts1 and the second scan transistor Ts2 may be effectively mitigated during the charging process of the storage capacitor Cst.

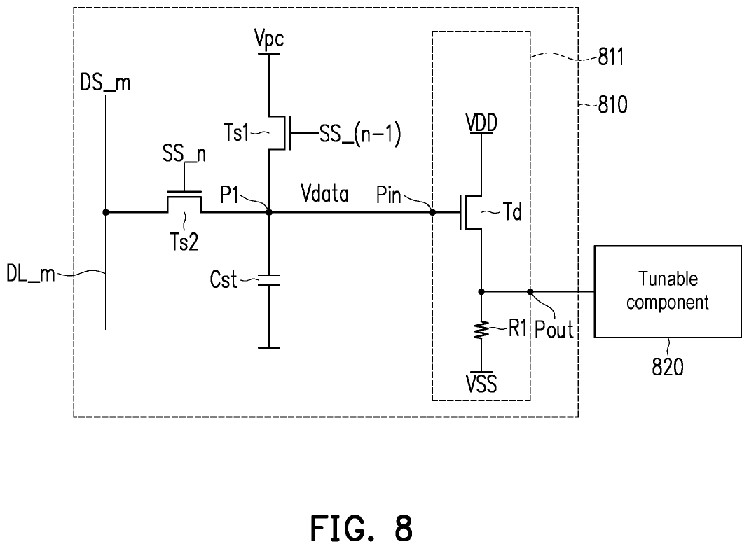

FIG. 8 is a schematic diagram of a pixel circuit and a tunable component according to an embodiment of the disclosure. Referring to FIG. 8, the pixel circuit 110 and the tunable component 120 of each of the electronic units P(1,1) to P(m,n) of FIG. 1 may be implemented as a pixel circuit 810 and a tunable component 820 of FIG. 8. Compared with FIG. 2, the pixel circuit 810 of FIG. 8 further includes a driving circuit 811, and the driving circuit 811 may be a voltage driver. Specifically, in the embodiment of the disclosure, the pixel circuit 810 includes a first scan transistor Ts1, a second scan transistor Ts2, a storage capacitor Cst, and a driving circuit 811. A first terminal of the first scan transistor Ts1 receives a pre-charge voltage Vpc. A second terminal of the first scan transistor Ts1 is coupled to a circuit node P1. A control terminal of the first scan transistor Ts1 receives a first scan signal SS_(n-1) from a scan line of a previous row of the pixel array. A first terminal of the second scan transistor Ts2 is coupled to a data line DL_m to receive a data signal DS_m. A second terminal of the second scan transistor Ts2 is coupled to the circuit node P1. A control terminal of the second scan transistor Ts2 receives a second scan signal SS_n from a scan line of a current row of the pixel array. A first terminal of the capacitor Cst is coupled to the circuit node P1. A second terminal of the capacitor Cst is coupled to a reference voltage, such as a ground voltage. An input node Pin of the driving circuit 811 is coupled to the circuit node P1, and an output node Pout of the driving circuit 811 is coupled to the tunable component 820.

In the embodiment of the disclosure, the driving circuit 811 includes a driving transistor Td and a resistor R1. A first terminal of the driving transistor Td is coupled to a first operation voltage VDD. A second terminal of the driving transistor Td is coupled to the output node Pout of the driving circuit 811 and a first terminal of the resistor R1. A control terminal of the driving transistor Td is coupled to the input node Pin of the driving circuit 811. A second terminal of the resistor R1 is coupled to a second operation voltage VSS. The first operation voltage VDD is higher than the second operation voltage VSS. In the embodiment of the disclosure, the driving transistor Td may be a n-type transistor, but the disclosure is not limited thereto. In the embodiment of the disclosure, the driving circuit 811 may drive the tunable component 820 according to a voltage Vdata(m,n) of the circuit node P1. The driving circuit 811 may effectively enhance driving capability of the pixel circuit 810. It should be noted that the driving circuit 811 may also be applied to the embodiments of FIG. 4 and FIG. 6 to integrate into the pixel circuit 410 of FIG. 4 and the pixel circuit 610 of FIG. 6.

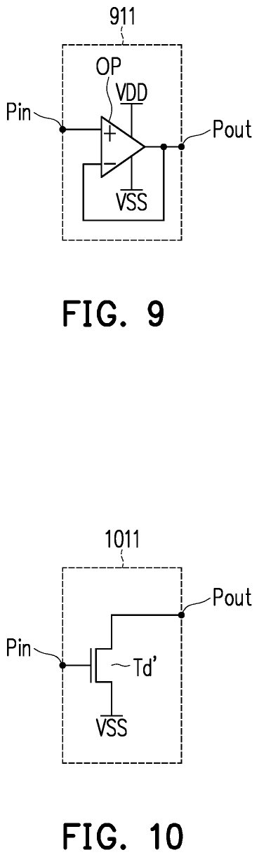

FIG. 9 is a schematic diagram of a driving circuit according to an embodiment of the disclosure. Referring to FIG. 9, in one embodiment of the disclosure, the driving circuit 811 of FIG. 8 may be replaced with the driving circuit 911 of FIG. 9. The driving circuit 911 includes an operational amplifier OP. The operational amplifier OP may be coupled to a first operation voltage VDD and a second operation voltage VSS. A non-inverting input terminal of the operational amplifier OP is coupled to an input node Pin of the driving circuit 911. An inverting input terminal of the operational amplifier OP is coupled to an output terminal of the operational amplifier OP. The output terminal of the operational amplifier OP is further coupled to an output node Pout of the driving circuit 911. The driving circuit 911 may also effectively enhance driving capability of the pixel circuit 810 of FIG. 8.

FIG. 10 is a schematic diagram of a driving circuit according to an embodiment of the disclosure. Referring to FIG. 10, in one embodiment of the disclosure, the driving circuit 811 of FIG. 8 may be replaced with the driving circuit 1011 of FIG. 10. The driving circuit 1011 may be a current driver, and the driving circuit 1011 includes a driving transistor Td′. A first terminal of the driving transistor Td′ is coupled to an output node Pout of the driving circuit 1011. A second terminal of the driving transistor Td′ is coupled to a second operation voltage VSS. A control terminal of the driving transistor Td′ is coupled to an input node Pin of the driving circuit 1011. The driving circuit 1011 may effectively convert a data voltage to a corresponding current to control the tunable component when the tunable component is a current-controlled component.

In summary, the electronic device of the disclosure may effectively alleviate the DAHC stress of the scan transistors in the pixel circuit by sharing the amount of charge to be transferred to the storage capacitor and the drain-source voltage through the scan transistors.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising:
a plurality of electronic units, wherein each of the plurality of electronic units comprises:
a pixel circuit; and
a tunable component, coupled to the pixel circuit,
wherein the pixel circuit comprises:
a storage capacitor;
a first scan transistor, coupled to the storage capacitor; and
a second scan transistor, coupled to the storage capacitor.

2. The electronic device according to claim 1, wherein the first scan transistor and the second scan transistor receive a first scan signal and a second scan signal respectively,
wherein the first scan transistor and the second scan transistor are turned-on at different times according to the first scan signal and the second scan signal.

3. The electronic device according to claim 1, wherein the second scan transistor is configured to transfer a data voltage to the storage capacitor.

4. The electronic device according to claim 3, wherein the second scan transistor is coupled to a data line to receive the data voltage.

5. The electronic device according to claim 3, wherein the first scan transistor is configured to transfer a pre-charge voltage to the storage capacitor.

6. The electronic device according to claim 5, wherein the pre-charge voltage is equal to or less than a maximum voltage of the data voltage, and the pre-charge voltage is equal to or larger than a minimum voltage of the data voltage.

7. The electronic device according to claim 6, wherein the pre-charge voltage is a fixed voltage.

8. The electronic device according to claim 7, wherein the pre-charge voltage is within a first preset range corresponding to a center of a voltage range of the data voltage.

9. The electronic device according to claim 6, wherein the first scan transistor receives the pre-charge voltage from a common voltage line shared with the plurality of electronic units on a same row and/or a same column.

10. The electronic device according to claim 6, wherein the pre-charge voltage is within a second preset range corresponding to a center of a voltage range of a first voltage,
wherein the first voltage is a current data voltage plus a previous data voltage divided by 2.

11. The electronic device according to claim 6, wherein the first scan transistor and the second scan transistor are coupled to a data line.

12. The electronic device according to claim 3, wherein the tunable component is controlled by a control signal corresponding to the data voltage.

13. The electronic device according to claim 12, wherein the tunable component is a voltage-controlled component.

14. The electronic device according to claim 12, wherein the tunable component is a capacitance tunable component.

15. The electronic device according to claim 3, wherein the pixel circuit further comprises:
a driving circuit, coupled to the tunable component.

16. The electronic device according to claim 15, wherein the driving circuit is a voltage driver.

17. The electronic device according to claim 1, wherein the electronic device is an active matrix device.

18. The electronic device according to claim 17, wherein the electronic device is an antenna device.

19. The electronic device according to claim 18, wherein the antenna device is a liquid crystal antenna.

20. The electronic device according to claim 18, wherein the antenna device is a varactor antenna.
